(19) United States
(12) Patent Application Publication
(10) Pub. No.: US 2025/0349692 A1
(43) Pub. Date: Nov. 13, 2025

(54) INTEGRATED CIRCUIT PACKAGE AND METHODS OF FORMING THE SAME

(71) Applicant: Taiwan Semiconductor Manufacturing Co., Ltd., Hsinchu (TW)

(72) Inventors: Chen-Shien Chen, Zhubei City (TW); Ting Hao Kuo, Hsinchu (TW); Hui-Chun Chiang, Zhunan Township (TW); Yu-Chia Lai, Zhunan Township (TW)

(21) Appl. No.: 19/277,580

(22) Filed: Jul. 23, 2025

Related U.S. Application Data
(63) Continuation of application No. 18/334,695, filed on Jun. 14, 2023.
(60) Provisional application No. 63/489,005, filed on Mar. 8, 2023.

(51) Int. Cl. H01L 23/498; H01L 21/48; H01L 21/768; H01L 23/00

(52) U.S. Cl. CPC H01L 23/49827; H01L 21/486; H01L 21/76829; H01L 24/06; H01L 2224/05025

(57) ABSTRACT

A device includes: a first integrated circuit (IC) die; a first dielectric material around first sidewalls of the first IC die; a second IC die over and electrically coupled to the first IC die; and a second dielectric material over the first dielectric material and around second sidewalls of the second IC die, where in a top view, the second sidewalls of the second IC die are disposed within, and are spaced apart from, the first sidewalls of the first IC die.

### PRIORITY CLAIM AND CROSS-REFERENCE

This application is a continuation of U.S. patent application Ser. No. 18/334,695, filed on Jun. 14, 2023 and entitled “Integrated Circuit Package and Methods of Forming the Same,” which claims the benefit of U.S. Provisional Application No. 63/489,005, filed on Mar. 8, 2023, which applications are hereby incorporated herein by reference in their entireties.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a wafer including a plurality of integrated circuit dies.

FIGS. 2-7, 8A, 8B, 9, 10, and 11A-11D are various views of an integrated circuit package at various stages of manufacturing, in accordance with an embodiment.

FIGS. 12A and 12B illustrate a cross-sectional view and a top view, respectively, of an integrated circuit package, in accordance with another embodiment.

FIGS. 13A and 13B illustrate a cross-sectional view and a top view, respectively, of an integrated circuit package, in accordance with another embodiment.

FIGS. 14A and 14B illustrate a cross-sectional view and a top view, respectively, of an integrated circuit package, in accordance with another embodiment.

FIG. 15 illustrate a cross-sectional view of an integrated circuit package, in accordance with another embodiment.

FIGS. 16A and 16B illustrate a cross-sectional view and a top view, respectively, of an integrated circuit package, in accordance with yet another embodiment.

FIG. 17 is a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion herein, unless otherwise specified, the same or similar reference numerals in different figures refer to the same or similar element formed in a same or similar process using a same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an integrated circuit package includes a first die (e.g., a lower die) and a second die (e.g., an upper die) over and electrically couple to the first die. A first liner layer and a first gap-filling material surround the first die. A second liner layer and a second gap-filling material surround the second die. In some embodiments, in a top view, second sidewalls of the second die are disposed within, and spaced apart from, first sidewalls of the first die. In other words, the second die is disposed within a boundary defined by the first sidewalls of the first die, and there is a lateral offset between a sidewall of the second die and a closest sidewall of the first die. The lateral offset between the two corresponding sidewalls of the first die and second die reduces the stress at the interface between the first die and the second die, and reduces the likelihood of delamination and/or warpage in the integrated circuit package.

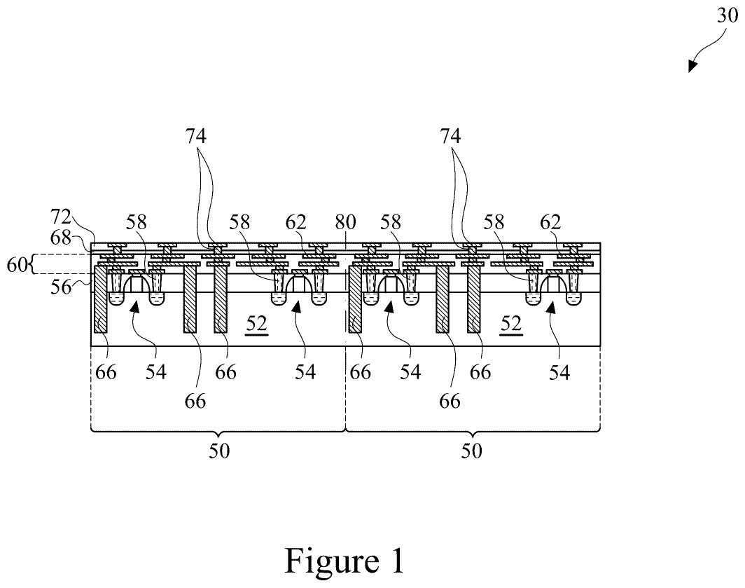

FIG. 1 illustrates a cross-sectional view of a wafer 30 including a plurality of integrated circuit dies 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, wide input/output (WIO) memory, NAND flash, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), an integrated passive device (IPD), the like, or combinations thereof.

The wafer 30 may be processed according to applicable manufacturing processes to form integrated circuits in the integrated circuit dies 50. For example, each of the integrated circuit dies 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back-side.

Devices 54 (represented by transistors) may be formed at the front surface of the semiconductor substrate 52. The devices 54 may be, e.g., transistors, diodes, capacitors, resistors, or the like. For example, the devices 54 may be transistors that include gate structures and source/drain regions, where the gate structures are on channel regions, and the source/drain regions are adjacent to the channel regions. The channel regions may be patterned regions of the semiconductor substrate 52. For example, the channel regions may be regions of semiconductor fins, semiconductor nanosheets, semiconductor nanowires, or the like patterned in the semiconductor substrate 52. When the devices 54 are transistors, they may be nanostructure field-effect transistors (Nanostructure-FETs), fin field-effect transistors (FinFETs), planar transistors, or the like. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Contacts 58 extend through the ILD 56 to electrically and physically couple the devices 54. For example, when the devices 54 are transistors, the contacts 58 may couple the gates and source/drain regions of the transistors to other circuit components. The contacts 58 may be formed of tungsten, cobalt, nickel, copper, silver, gold, aluminum, the like, or combinations thereof. An interconnect structure 60 is over the ILD 56 and contacts 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns of the interconnect structure 60 are electrically coupled to the devices 54 by the contacts 58. In some embodiments, passive devices are also formed in the interconnect structure 60. FIG. 1 also illustrates pads 62, such as aluminum pads, to which external connections are made. The pads 62 are on the active side of the integrated circuit dies 50, such as in and/or on the interconnect structure 60.

As illustrated in FIG. 1, conductive vias 66 extend into the interconnect structure 60 and/or the semiconductor substrate 52. The conductive vias 66 are electrically coupled to the pads 62 and/or the metallization patterns of the interconnect structure 60. The conductive vias 66 may be through-substrate vias (TSVs), such as through-silicon vias. As an example to form the conductive vias 66, recesses can be formed in the interconnect structure 60 and/or the semiconductor substrate 52 by, for example, etching, milling, laser techniques, a combination thereof, or the like. A thin barrier layer may be conformally deposited in the recesses, such as by CVD, atomic layer deposition (ALD), physical vapor deposition (PVD), a combination thereof, or the like. The barrier layer may include titanium, titanium nitride, tantalum, tantalum nitride, combinations thereof, or the like. A conductive material may be deposited over the barrier layer and in the recesses. The conductive material may be formed by electroplating, electroless plating, CVD, ALD, PVD, a combination thereof, or the like. Examples of the conductive material include copper, silver, gold, tungsten, cobalt, aluminum, nickel, alloy thereof, a combination thereof, or the like. In some embodiments, the conductive material is copper. Excess conductive material and barrier layer are removed by, for example, a chemical-mechanical polish (CMP). The remaining portions of the barrier layer and conductive material in the recesses form the conductive vias 66.

In the illustrated embodiment, the conductive vias 66 are formed by a via-middle process, such that the conductive vias 66 extend through a portion of the interconnect structure 60 and extend into the semiconductor substrate 52. The conductive vias 66 formed by the via-middle process are connected to a middle metallization pattern of the interconnect structure 60. In another embodiment, the conductive vias 66 are formed by a via-first process, such that the conductive vias 66 extend into the semiconductor substrate 52 but not the interconnect structure 60. The conductive vias 66 formed by a via-first process are connected to a lower metallization pattern of the interconnect structure 60. In yet another embodiment, the conductive vias 66 are formed by a via-last process, such that the conductive vias 66 extend through an entirety of the interconnect structure 60 and extend into the semiconductor substrate 52. The conductive vias 66 formed by the via-last process are connected to the upper metallization pattern of the interconnect structure 60.

One or more passivation layer(s) 68 are disposed on the interconnect structure 60. The passivation layer(s) 68 may be formed of one or more suitable dielectric materials such as silicon oxynitride, silicon nitride, low-k dielectrics such as carbon doped oxides, extremely low-k dielectrics such as porous carbon doped silicon oxide, a polymer such as polyimide, solder resist, polybenzoxazole (PBO), a benzocyclobutene (BCB) based polymer, molding compound, the like, or a combination thereof. The passivation layer(s) 68 may be formed by chemical vapor deposition (CVD), spin coating, lamination, the like, or a combination thereof. In some embodiments, the passivation layer(s) 68 include a silicon oxynitride layer or a silicon nitride layer.

A dielectric layer 72 is disposed on the passivation layer(s) 68. The dielectric layer 72 may be formed of an oxide such as silicon oxide, phosphosilicate glass (PSG), borosilicate glass (BSG), or boron-doped phosphosilicate glass (BPSG); a nitride such as silicon nitride or silicon oxynitride; combinations thereof; or the like. The dielectric layer 72 may be formed, for example, by CVD, spin coating, lamination, or the like. In some embodiments, the dielectric layer 72 is formed of silicon oxide.

Die connectors 74 extend through the dielectric layer 72 and the passivation layer(s) 68. The die connectors 74 may include conductive pillars, pads, or the like, to which external connections can be made. In some embodiments, the die connectors 74 include bond pads at the front-side surface of the integrated circuit die 50, and include post-pad vias that connect the bond pads to the interconnect structure 60. In such embodiments, the die connectors 74 (including the bond pads and the post-pad vias) may be formed by a damascene process, such as a single damascene process, a dual damascene process, or the like. The die connectors 74 can be formed of a conductive material, such as a metal, such as copper or its alloy, or the like, which can be formed by, for example, electroplating, electroless plating, CVD, PVD, or the like. In some embodiments, after the die connectors 74 and the dielectric layer 72 are formed, the wafer 30 may be singulated along the scribe lines 80, so that the integrated circuit dies 50 are separated and can be picked up individually.

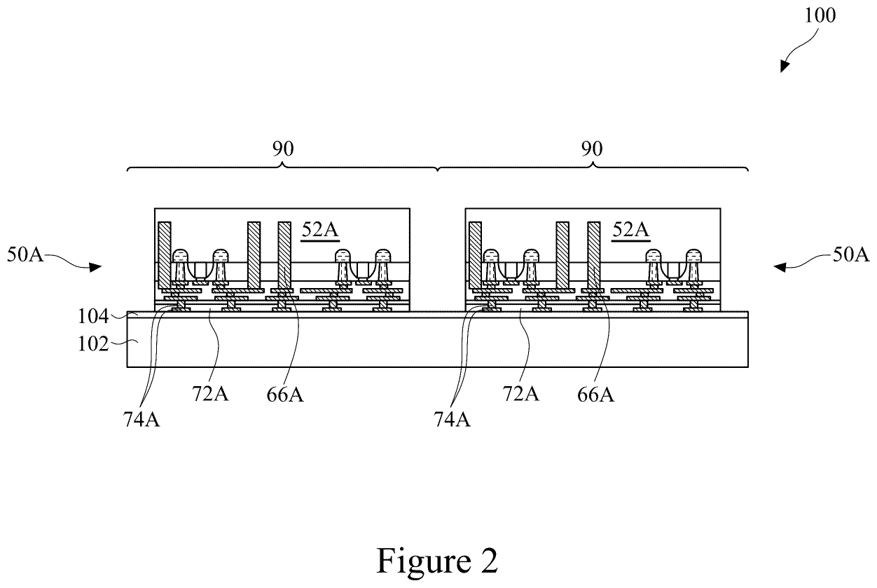

FIGS. 2-11D are various views (e.g., cross-sectional views, top views) of an integrated circuit packages 100 at various stages of manufacturing, in accordance with an embodiment. The integrated circuit packages 100 may be formed by packaging multiple integrated circuit dies 50 at a wafer level and then performing a singulation (e.g., dicing) process, such that each of the integrated circuit packages may include one or more the integrated circuit dies 50. The integrated circuit packages 100 may be system-on-integrated-chips (SoIC) devices, although other types of packages may be formed.

Next, in FIG. 2, a carrier substrate 102 is provided. The carrier substrate 102 may be a glass carrier substrate, a ceramic carrier substrate, or the like. The carrier substrate 102 may be a wafer, such that multiple packages can be formed on the carrier substrate 102 simultaneously in different regions 90 of the wafer. Integrated circuit dies 50A are attached to the carrier substrate 102, in accordance with some embodiments. The integrated circuit dies 50A may be the same as or similar to the integrated circuit die 50 as described for FIG. 1. Similar features in the integrated circuit die 50A may not be separately labeled or may be labeled with the same referencing numeral followed by a letter “A” (e.g., 66A, 74A). The integrated circuit dies 50A may be attached to the carrier substrate 102 in a face-down manner, such that the front-sides of the integrated circuit dies 50A are attached to the carrier substrate 102. The integrated circuit dies 50A may be placed by, e.g., a pick-and-place process.

The integrated circuit dies 50A may be attached to the carrier substrate 102 by bonding the integrated circuit dies 50A to the carrier substrate 102 with a release layer 104. The release layer 104 is on a surface of the carrier substrate 102. In some embodiments, the release layer 104 is a thermal-release material, which loses its adhesive property when heated, such as a light-to-heat-conversion (LTHC) release coating; an ultra-violet (UV) glue, which loses its adhesive property when exposed to UV lights; or the like. The release layer 104 may be dispensed as a liquid and cured, or may be a laminate film laminated onto the carrier substrate 102 before the attachment of the integrated circuit dies 50A.

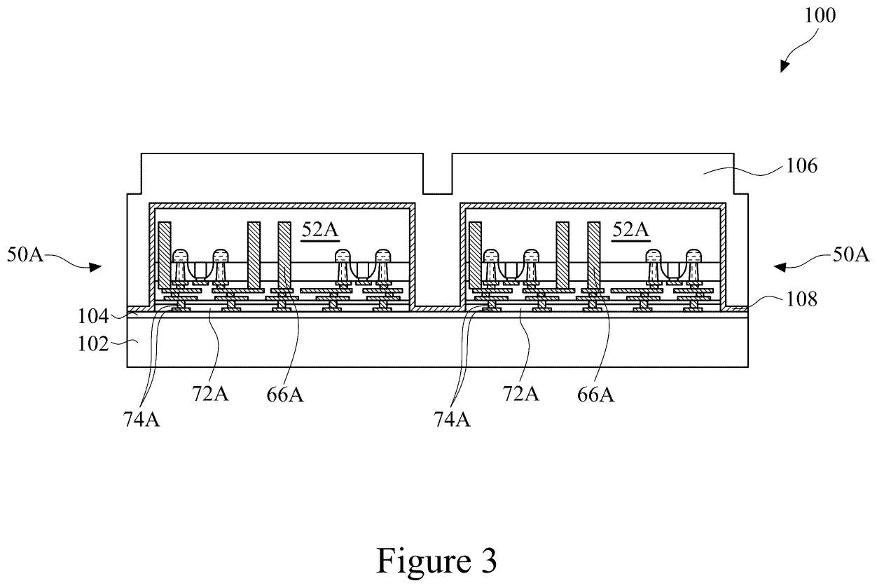

Next, in FIG. 3, a dielectric liner 108 and a dielectric layer 106 are formed on the integrated circuit dies 50A and on the release layer 104 over the carrier substrate 120. The dielectric liner 108 (also referred to as a dielectric liner layer 108, a liner material 108, a liner layer 108, or a liner 108) and the dielectric layer 106 (also referred to as a gap-filling material 106, or a gap-filling layer 106) may be collectively referred to as gap-filling layers. The dielectric liner 108 may be formed as a conformal layer, and may be formed of a dielectric material having good adhesion to the release layer 104 and the integrated circuit dies 50A. Acceptable material of the dielectric liner 108 may include a nitride such as silicon nitride, silicon carbonitride, silicon oxynitride, silicon oxycarbonitride, or the like, which may be formed by a suitable deposition method such as CVD, PVD, ALD, combinations thereof, or the like. The liner layer 108 may help stop cracking in the gap-filling material 106 from propagating to, and damaging, the integrated circuit dies 50A. In the illustrated embodiment, the dielectric liner 108 is a single-layer dielectric material (e.g., having a homogeneous composition).

The gap-filling layer 106 may be formed of a material different from the material of the dielectric liner 108. In some embodiments, the gap-filling layer 106 is formed of an oxide, such as silicon oxide, PSG, BSG, BPSG, or the like. In some embodiments, the gap-filling layer 106 is formed of a polymer material such as polyimide. In some embodiments, the gap-filling layer 106 is formed of a molding material. The gap-filling layer 106 may be formed using CVD, high-density plasma CVD (HDPCVD), flowable CVD, spin-on coating, or the like. The gap-filling layer 106 may fill gaps between adjacent integrated circuit dies 50A, and may overfill the gaps such that the gap-filling layer 106 covers the upper surfaces (e.g., back-sides) of the integrated circuit dies 50A.

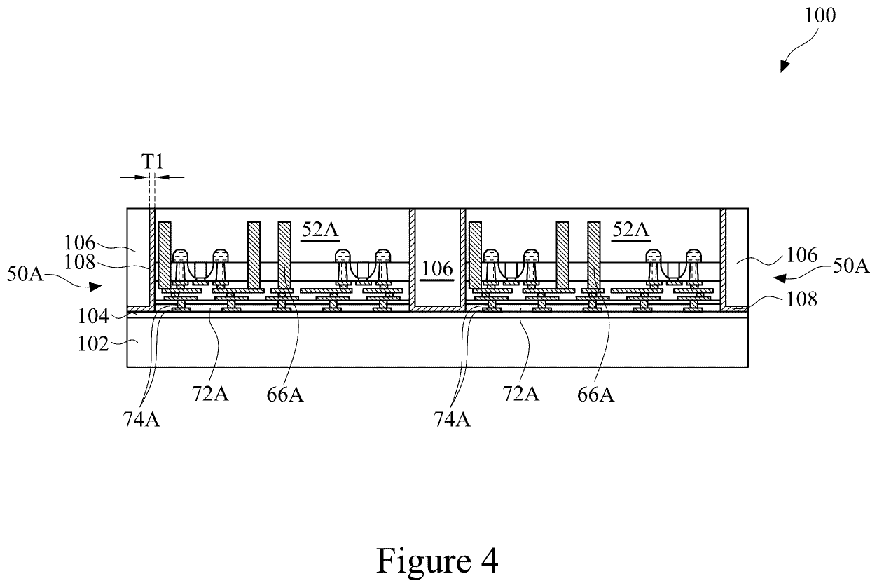

Next, in FIG. 4, a removal process is performed to level surfaces of the gap-filling layer 106 and the dielectric liner 108 with the back-side surfaces of the integrated circuit dies 50A (e.g., the back-side surfaces of the semiconductor substrates 52A). In some embodiments, the removal process may be a chemical mechanical polish (CMP), grinding, an etch-back process, combinations thereof, or the like. After the removal process, excess portions of the gap-filling layer 106 and liner 108 over the back-side surfaces of the integrated circuit dies 50A are removed. In some embodiments, the removal process also includes removing a portion of the semiconductor substrates 52A of the integrated circuit dies 50A, though the conductive vias 66A may remain buried by the semiconductor substrates 52A after the removal process.

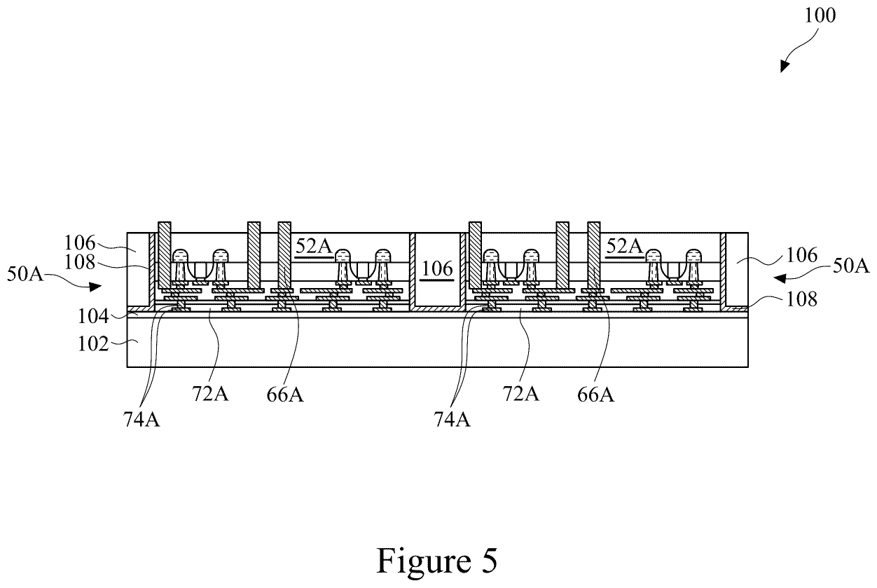

Next, in FIG. 5, the semiconductor substrates 52A are recessed to expose the conductive vias 66A. Portions of the gap-filling layer 106 and portions of the liner 108 may also be removed by the recessing process. The recessing process may be, for example, an etch-back process, or the like, which is performed at the back-sides of the integrated circuit dies 50A. In some embodiments, the recessing process may be a combination of the etch-back process with CMP or a grinding process, such as performing the etch-back process to expose sidewalls of the conductive vias 66A after performing the CMP or the grinding process to expose the top of the conductive via 66A.

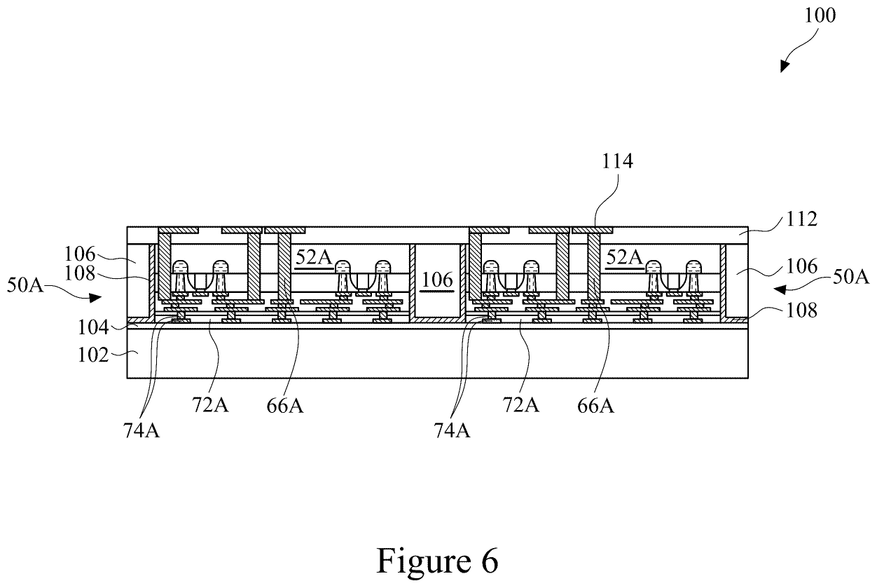

Next, in FIG. 6, a bonding film 112 is formed around the conductive vias 66A of each integrated circuit die 50A and over the gap-filling layer 106 and the liner 108. For example, the bonding film 112 may bury or cover the conductive vias 66A. The bonding film 112 can help electrically isolate the conductive vias 66A from one another, thus avoiding electrical shorting, and can also be utilized in a subsequent bonding process. The bonding film 112 may be a single layer or a composite layer including a plurality of sublayers. The single layer or the sublayers of the bonding film 112 may include an oxide such as silicon oxide, phosphosilicate glass (PSG), borosilicate glass (BSG), or boron-doped phosphosilicate glass (BPSG); an oxynitride such as silicon oxynitride; combinations thereof; a polymer such as polyimide; or the like. The bonding film 112 may be formed by a suitable deposition process such as CVD, PVD, coating, other suitable deposition methods, combinations thereof, or the like. In some embodiments, the as-deposited bonding film 112 includes protrusions (not shown) over the conductive vias 66A, and a planarization process, such as CMP, grinding, or an etch-back process, may be optionally performed to remove protrusions of the bonding film 112 for facilitating the subsequent processes for forming bonding pads 114. The bonding film 112 may continuously extend over the gap-filling layer 106, the liner 108, and the integrated circuit dies 50A. In some embodiments, the bonding film 112 has a thickness of 0.02 μm to 2 μm.

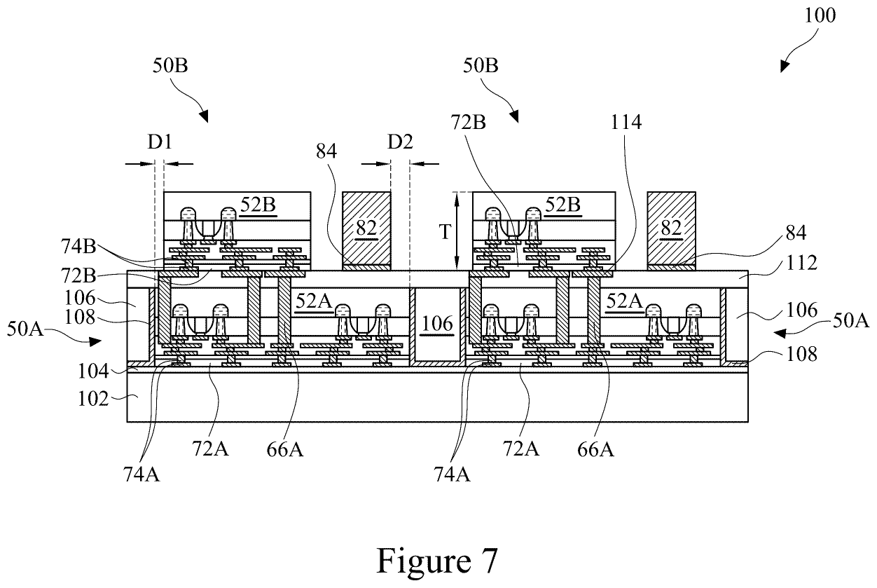

Next, bonding pads 114 are formed over respective conductive vias 66A, in the illustrated embodiment. The bonding pads 114 may include a material similar to the conductive vias 66A. In some embodiments, the bonding pads 114 include a multi-layer structure, such as including a main layer and a barrier layer surrounding a bottom and sidewalls of the main layer. The main layer may include copper or other low-resistance material such as copper alloy, silver, gold, tungsten, cobalt, aluminum, nickel, a combination thereof, or the like, and the barrier layer may include titanium, titanium nitride, tantalum, tantalum nitride, combinations thereof, or the like. The formation of the bonding pads 114 may include etching the bonding film 112 for forming openings for the bonding pads 114, which expose the conductive vias 66A. Materials of the bonding pads 114 may then be deposited in the openings and over the bonding film 112, such as by electroplating, electroless plating, CVD, ALD, PVD, combinations thereof, or the like. Excess material of the bonding pads 114 over the bonding film 112 may be removed by a planarization process, such as CMP or grinding. In some embodiments, the bonding pads 114 have a size greater than the size of conductive vias 66A in a plan view, which may facilitate the subsequent attachment of the integrated circuit dies 50B (e.g., see FIG. 7). For example, a length and/or a width of the bonding pads 114 may be greater than a height of the bonding pads 114.

Next, in FIG. 7, integrated circuit dies 50B are attached to the integrated circuit dies 50A. The integrated circuit dies 50B may be the same as or similar to the integrated circuit die 50 of FIG. 1. Similar features in the integrated circuit die 50B may not be separately labeled or may be labeled with the same referencing numeral followed by a letter “B” (e.g., 52B). In some embodiments, the integrated circuit dies 50B have a different function from the integrated circuit dies 50A. As an example, the integrated circuit dies 50A are logic dies, and the integrated circuit dies 50B are memory dies. The integrated circuit dies 50B may be attached to the bonding film 112 in a face-to-back manner, such that the front-sides of the integrated circuit dies 50B are attached to the back-sides of the integrated circuit dies 50A. The integrated circuit dies 50B may be placed by, e.g., a pick-and-place process. Besides the face-to-back bonding, other ways of bonding are also possible. More examples are discussed hereinafter.

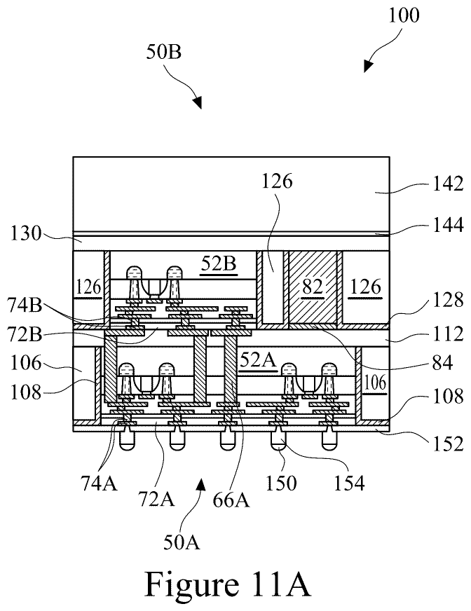

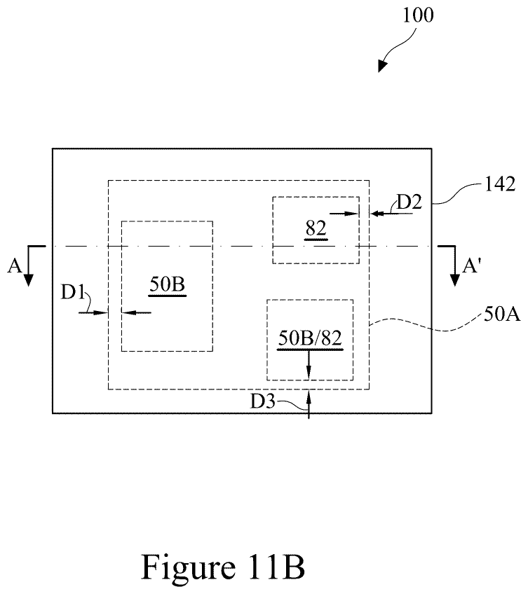

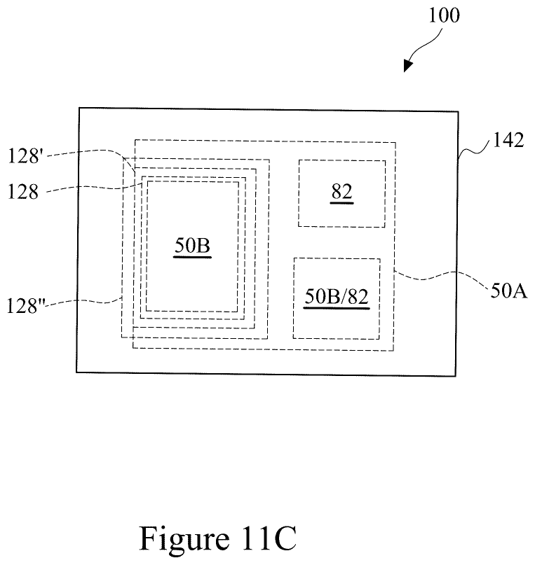

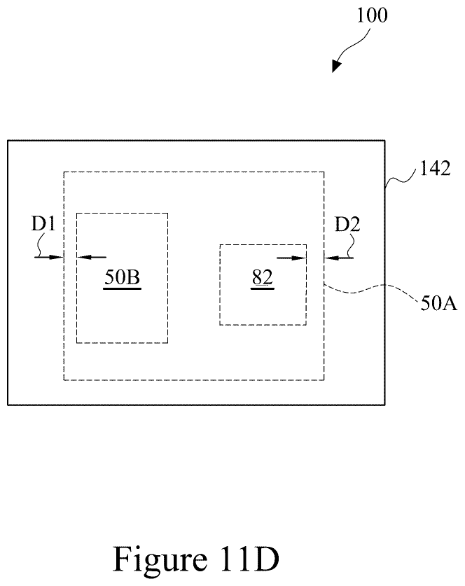

In some embodiments, each integrated circuit die 50B is attached to the corresponding underlying integrated circuit die 50A (e.g., through the bonding film 112) such that in a top view, the sidewalls of the integrated circuit die 50B are disposed within, and spaced apart from, the sidewalls of the integrated circuit die 50A. In other words, in the top view, the integrated circuit die 50B is disposed within a perimeter (e.g., a boundary) defined by the sidewalls of the integrated circuit die 50A, and there is a lateral offset between a sidewall of the integrated circuit die 50B and a closest sidewall of the integrated circuit die 50A. FIG. 7 illustrates a lateral offset D1 between a sidewall of the integrated circuit die 50B and a closest sidewall of the integrated circuit die 50A, which lateral offset D1 may be the minimum lateral offset among all of the lateral offsets between the sidewalls of the integrated circuit die 50B and the sidewalls of the integrated circuit die 50A. Examples of the top view of the integrated circuit package 100 are illustrated in FIGS. 11B-11D.

In some embodiments, the lateral offset D1 (e.g., the minimum lateral offset), is larger than 0 μm, such as between 0 μm and about 80 μm (80 μm>D1>0 μm). For example, the lateral offset D1 may be larger than 3 μm (e.g., D1>3 μm), larger than 5 μm (e.g., D1>5 μm), larger than 10 μm (e.g., D1>10 μm), lager than 15 μm (e.g., D1>15 μm), or larger than 20 μm (e.g., D1>20 μm). In some embodiments, the lateral offset D1 (e.g., the minimum lateral offset) is larger than one third of a thickness T of the integrated circuit die 50B (e.g., D1>(⅓)T), where the thickness T is measured between an upper surface and a lower surface of the integrated circuit die 50B.

The integrated circuit dies 50B may be bonded to the bonding film 112 by direct bonding. The dielectric layer 72B (e.g., the exterior dielectric layer distal from the substrate 52B of the integrated circuit die 50B) of the integrated circuit die 50B is directly bonded to the bonding film 112 through dielectric-to-dielectric bonding, preferably without using any adhesive material. The die connectors 74B of the integrated circuit die 50B are directly bonded to respective bonding pads 114 over the conductive vias 66A of the integrated circuit die 50A through metal-to-metal bonding, preferably without using any eutectic material (e.g., solder). The bonding may include a pre-bonding and an annealing. In some embodiments, during the pre-bonding, a small pressing force is applied to press the integrated circuit dies 50B against the integrated circuit dies 50A. The pre-bonding is performed at a low temperature, such as a temperature in the range of 15° C. to 30° C. The bonding strength is then improved in a subsequent annealing step, in which the bonding film 112, the bonding pads 114, the dielectric layers 72B, and the die connectors 74B are annealed. After the annealing, direct bonds such as fusion bonds are formed, bonding the dielectric layers 72B to the bonding film 112. For example, the bonds can be covalent bonds between the material of the dielectric layer 72B and the material of the bonding film 112. The bonding pads 114 disposed over the conductive vias 66A are connected to the die connectors 74B with a one-to-one correspondence. During the annealing, the material of bonding pads 114 (e.g., copper) and the material of die connectors 74B (e.g., copper) are intermingled, so that metal-to-metal bonds are also formed. Hence, the resulting bonds between the integrated circuit dies 50B and the integrated circuit dies 50A include both dielectric-to-dielectric bonds (e.g., dielectric layers 72B to bonding film 112) and metal-to-metal bonds (die connectors 74B to bonding pads 114). Respective ones of the bonded integrated circuit dies 50A and 50B are thus electrically coupled.

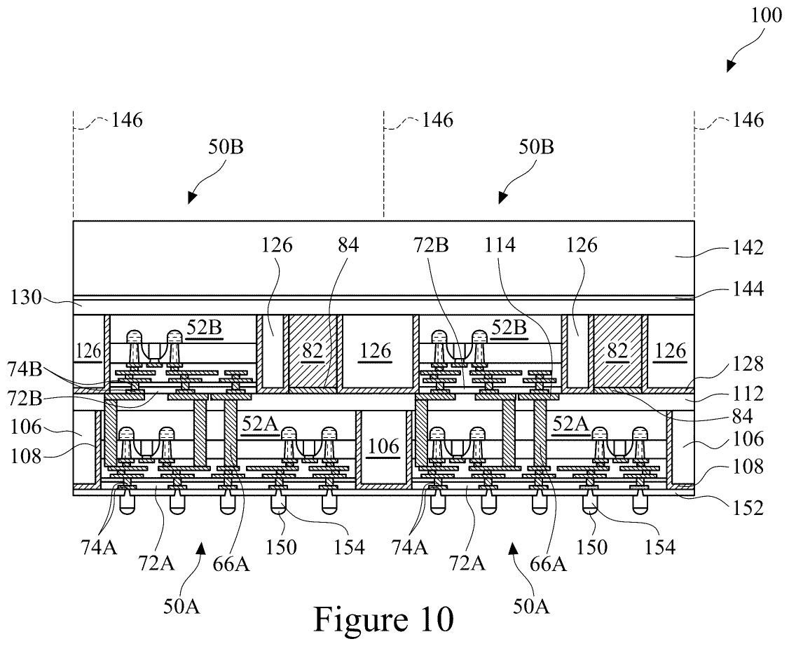

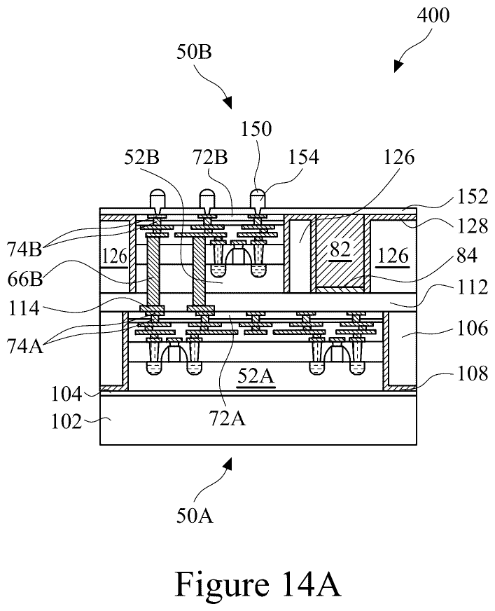

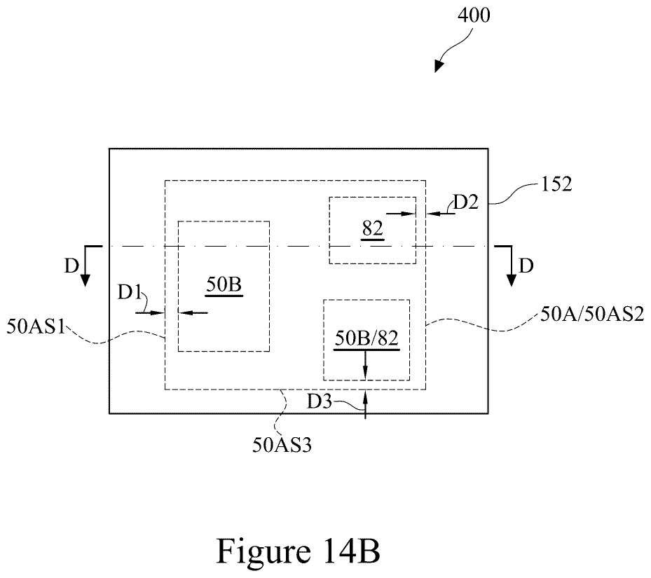

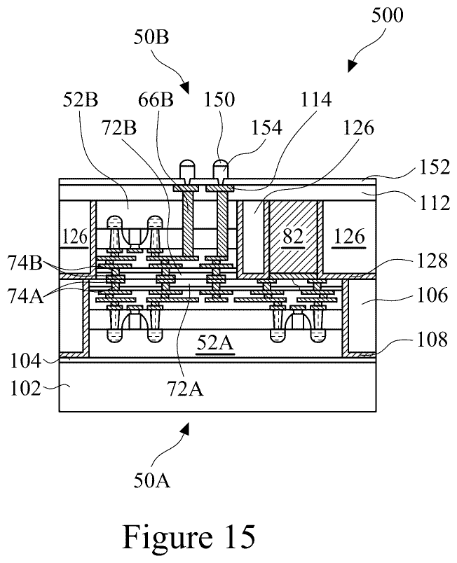

In the example of FIG. 7, the integrated circuit dies 50B do not include conductive vias 66 (e.g., TSVs). The integrated circuit (IC) packages 100 include two layers of integrated circuit dies (e.g., 50A and 50B), and the conductive vias 66 are excluded from the integrated circuit dies 50B because the integrated circuit dies 50B are the upper layer of integrated circuit dies in the IC package 100, and external connectors (see, e.g., 154 in FIG. 10) of the IC packages 100 are formed on the lower layer of integrated circuit dies 50A. In some embodiments, the IC packages 100 include more than two layers of integrated circuit dies, and the conductive vias 66 may be formed in each layer of the integrated circuit dies except for the uppermost layer of integrated circuit dies. In yet other embodiments, the uppermost layer could include conductive vias 66, thus allowing for even greater flexibility in interconnecting the IC package 100 to other components (see, e.g., FIGS. 14A and 15).

FIG. 7 further illustrates a dummy die 82 attached to a respective underlying integrated circuit die 50A through the bonding film 112. The dummy die 82 may be attached to the bonding film 112 through a dielectric film 84 (e.g., through dielectric-to-dielectric bonding between the dielectric film 84 and the bonding film 112). In the example of FIG. 7, the conductive vias 66A (e.g., TSVs) in each integrated circuit die 50A are formed in a region under (e.g., directly under) the integrated circuit die 50B, and there is no conductive via 66A under (e.g., directly under) the dummy die 82.

In some embodiments, the dummy die 82 does not have electrical components (e.g., transistors, diodes, capacitors, inductors, or the like) formed therein, and does not perform any signal processing function. The dummy die 82 may or may not include any conductive lines (e.g., copper lines). In some embodiments, the dummy die 82 includes some conductive lines (e.g., copper lines), but the conductive lines are electrically isolated. The dummy die 82 may be used in the IC package 100 for the purpose of, e.g., structural support, or heat dissipation. The dummy die 82 may be a silicon dummy die (e.g., formed of a bulk silicon), with or without metal patterns (e.g., copper lines) formed therein. In embodiments where the dummy die 82 is a silicon dummy die, the dielectric film 84 may comprise an oxide such as silicon oxide, a nitride such as silicon nitride, or the like. In some embodiments, the dummy die 82 is a ceramic die (e.g., formed of a bulk ceramic material) used to help heat dissipation, and the dielectric film 84 is a thermal-interface-material (TIM).

In the example of FIG. 7, each dummy die 82 is attached to the bonding film 112 such that in a top view, the sidewalls of the dummy die 82 are disposed within, and spaced apart from, the sidewalls of the underlying integrated circuit die 50A. In other words, in the top view, the dummy die 82 is disposed within a perimeter (e.g., a boundary) defined by the sidewalls of the integrated circuit die 50A, and there is a lateral offset between a sidewall of the dummy die 82 and a closest sidewall of the integrated circuit die 50A. FIG. 7 illustrates a lateral offset D2 between a sidewall of the dummy die 82 and a closest sidewall of the integrated circuit die 50A, which lateral offset D2 may be the minimum lateral offset among all of the lateral offsets between the sidewalls of the dummy die 82 and the sidewalls of the integrated circuit die 50A.

In some embodiments, the lateral offset D2 (e.g., the minimum lateral offset), is larger than 0 μm, such as between 0 μm and about 80 μm (80 μm>D2>0 μm). In some embodiments, the lateral offset D2 (e.g., the minimum lateral offset) is larger than one third of a thickness T of the integrated circuit die 50B (e.g., D2>(⅓)T), or larger than one third of a thickness of the dummy die 82. Details are the same as or similar to those of the lateral offset D1, thus not repeated here.

The lateral offsets between sidewalls of the integrated circuit die 50A and sidewalls of the integrated circuit die 50B help to reduce stress at the interface between the integrated circuit die 50A and the integrated circuit die 50B, and therefore, help to reduce or prevent the occurrence of delamination and warpage in the IC package 100. To appreciate the advantage, consider a reference design where at least one sidewall of the integrated circuit die 50B is aligned (e.g., vertically aligned) with a sidewall of the integrated circuit die 50A. Due to variations in the manufacturing process, the integrated circuit die 50B, after being attached, may overhang the integrated circuit die 50A. In other words, a sidewall of the integrated circuit die 50B may extend beyond the underlying sidewall of the integrated circuit die 50A, and therefore, a portion of the integrated circuit die 50B may be directly over the first gap-filling material 106, or even directly contact the first gap-filling material 106 in embodiments (see, e.g., FIG. 15) where the integrated circuit dies 50A and 50B are in direct contact. Since there may be a large difference in the coefficient of thermal expansion (CTE) of the first gap-filling material 106 and the (average) CTE of the integrated circuit die 50B, during thermal process(es) (e.g., the annealing process to bond the integrated circuit die 50B to the integrated circuit die 50A), a large amount of stress may occur at or near the interface between the integrated circuit dies 50A and 50B, such as at the lower corner of the overhang portion of the integrated circuit die 50B. The large amount of stress may cause delamination of the bonding film 112, and/or peeling off of the integrated circuit die 50B from the integrated circuit die 50A, and additionally, may cause warpage of the IC package 100. The presently disclosure embodiments, by having the lateral offsets between sidewalls of the integrated circuit dies 50A and 50B, ensures that the integrated circuit die 50B does not overhang the underlying integrated circuit die 50A, thus reducing or preventing the issues caused by the overhang, such as delamination of the bonding film 112, peeling off of the semiconductor die 50B, and warpage of the IC package 100. Similar advantage is achieved by the lateral offsets between sidewalls of the dummy die 82 and sidewalls of the integrated circuit die 50A, as skilled artisans readily appreciate.

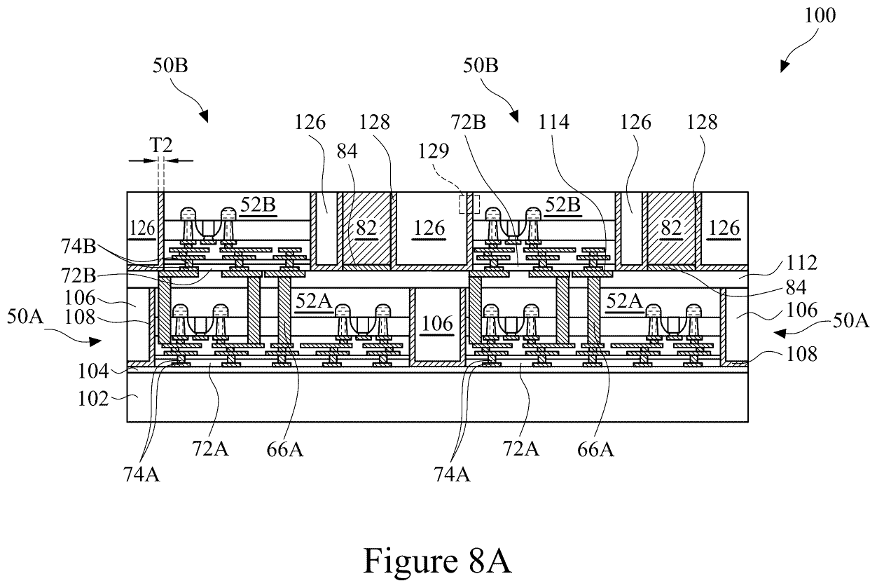

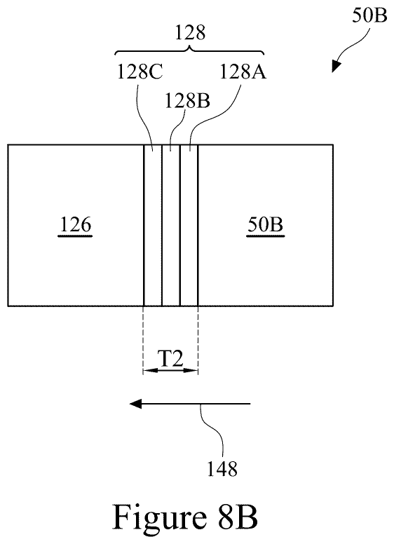

Next, in FIG. 8A, a dielectric liner 128 and a dielectric layer 126 are formed on the integrated circuit dies 50B, the dummy dies 82, and the bonding film 112. The dielectric liner 128 (also referred to as a dielectric liner layer 128, a liner material 128, a liner layer 128, or a liner 128) and the dielectric layer 126 (also referred to as a gap-filling material 126, or a gap-filling layer 126) may be collectively referred to as gap-filling layers. The dielectric liner 128 may be formed as a conformal layer, and may be formed of a dielectric material having good adhesion to the bonding film 112 and the integrated circuit dies 50B. Acceptable material of the dielectric liner 128 may include a nitride such as silicon nitride, silicon carbonitride, silicon oxynitride, silicon oxycarbonitride, or the like, which may be formed by a suitable deposition method such as CVD, PVD, ALD, combinations thereof, or the like. The liner layer 128 may help stop cracking in the gap-filling material 126 from propagating to, and damaging, the integrated circuit dies 50B.

In some embodiments, the dielectric liner 128 is formed of a material that is softer than that of the dielectric liner 108. For example, the Young's modulus of the dielectric liner 128 is smaller than the Young's modulus of the dielectric liner 108. The soft material of the dielectric liner 128 helps to reduce stress at or near the interface between the integrated circuit dies 50A and 50B. As a non-limiting example, the dielectric liner 128 is formed of a polymer material, such as polyimide, and the dielectric liner 108 is formed of a nitride, such as silicon nitride. In addition to being formed of a different material (e.g., softer material) than the dielectric liner 108, the dielectric liner 128 may be formed to have a thickness T2 that is different from a thickness T1 (see FIG. 4) of the dielectric liner 108. For example, the thickness T2 may be larger than the thickness T1.

In some embodiment, the dielectric liner 128 is a single-layer dielectric material (e.g., having a homogeneous composition). In other embodiments, the dielectric liner 128 has a multiple-layered structure (e.g., having an inhomogeneous composition, or a heterogeneous composition) comprising a plurality of sublayers, where each sublayer is formed of a different dielectric material. An example is illustrated in FIG. 8B.

FIG. 8B illustrates a zoomed-in view of an area 129 of the IC package 100. In the example of FIG. 8B, the dielectric liner 128 includes a plurality of sublayers labeled as 128A, 128B, and 128C. Although three sublayers are illustrated in FIG. 8B, the dielectric liner 128 may include other numbers of sublayers, such as two, four, or more than four. In an embodiment, the sublayer 128A, which contacts the integrated circuit die 50B, is formed of a soft material, such as polymer (e.g., polyimide); the sublayer 128C, which contacts the gap-filling material 126, is formed of a hard material, such as a nitride (e.g., silicon nitride); and the sublayer 128B, which is sandwiched between the sublayers 128A and 128C, is formed of a mixture of the material (e.g., polymer) of the sublayer 128A and the material (e.g. nitride) of the sublayer 128C, and therefore, has a hardness (e.g., measured by Young's modulus) between that of the sublayer 128A and that of the sublayer 128C. In some embodiments, the sublayer 128B is omitted, and the dielectric liner 128 has the sublayers 128A and 128C only. The sublayer 128A helps to reduced stress in the IC package 100, and the sublayer 128C helps to prevent cracking in the gap-filling material 126 from reaching the integrated circuit dies 50B.

In some embodiments, more than one sublayers are formed between the sublayers 128A and 128C of the dielectric liner 128, and there is a gradient in the hardness (e.g., measured by Young's modulus) of the sublayers of the dielectric liner 128. As an example, the hardness of the sublayers of the dielectric liner 128 increases along a direction (see arrow 148) from the sublayer 128A toward the sublayer 128C. In some embodiments, the sublayers of the dielectric liner 128 are formed using a mixture of a soft material (e.g., polymer) and a hard material (e.g., nitride), and the gradient in the hardness of the sublayers may be achieved by changing the mixing ratio (e.g., volume ratio) between, e.g., the polymer and the nitride. For example, the sublayer contacting the integrated circuit die 50B comprises polymer only (e.g., comprising 100% polymer), the sublayer contacting the gap-filling material 126 comprises nitride only (e.g., comprising 100% nitride), and other sublayers disposed in-between comprise a mixture of polymer and nitride. The percentage of polymer in the sublayers of the dielectric liner 128 decreases along the direction indicated by the arrow 148, and the percentage of nitride increases along the direction indicated by the arrow 148. In other words, the mixing ratio of polymer to nitride decreases along the direction indicated by the arrow 148, in some embodiments.

Still referring to FIGS. 8A and 8B, the gap-filling layer 126 may be formed of a same or similar material as the gap-filling material 106, using a same or similar formation method. Details are not repeated here. Next, a planarization process is performed to level the gap-filling layer 126 with the back-side surfaces of the integrated circuit dies 50B. In some embodiments, the planarization process may include CMP, grinding, an etch-back process, combinations thereof, or the like. After the planarization process, surfaces of the gap-filling layer 126 and the liner 128 and the back-side surfaces of the integrated circuit dies 50B are substantially coplanar (within process variations). In some embodiments, the planarization process also includes removing a portion of the semiconductor substrates 52B.

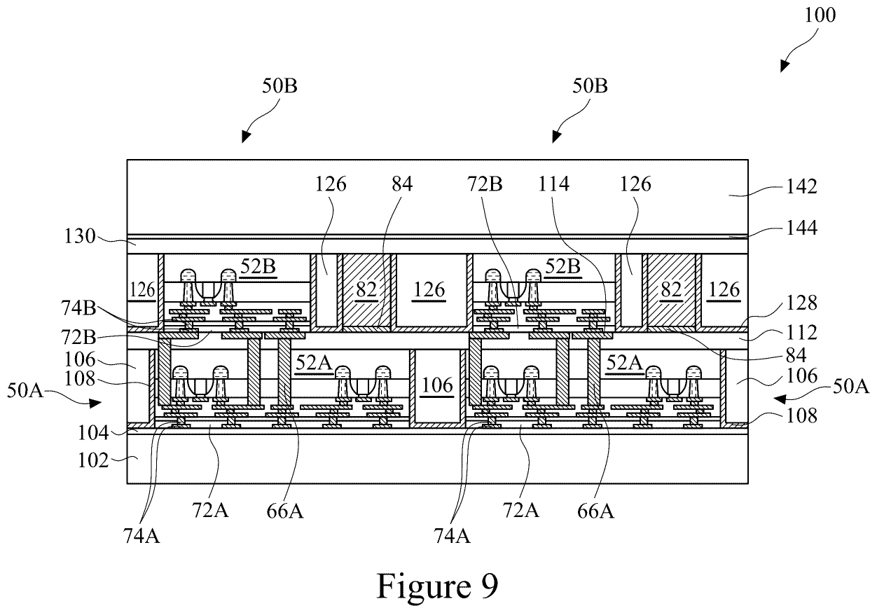

Next, in FIG. 9, a bonding film 130 is optionally formed over the integrated circuit dies 50B, the liner 128, and the gap-filling layer 126. The bonding film 130 may include a dielectric material. For example, the bonding film 130 may be a single layer or a composite layer including a plurality of sublayers. The single layer or the sublayers of the bonding film 130 may include an oxide such as silicon oxide, PSG, BSG, or BPSG; an oxynitride such as silicon oxynitride; an adhesive material such as die attach film (DAF) or thermal interface material (TIM); combinations thereof; or the like. The bonding film 130 may be formed by a suitable deposition process such as CVD, PVD, coating, laminating, combinations thereof, or the like.

Next, a support substrate 142 is attached to the integrated circuit dies 50B, the gap-filling layer 126, and the liner 128. The support substrate 142 may be a blank silicon substrate, in a die form or a wafer form. The support substrate 142 may be attached to the integrated circuit dies 50B, the liner 128, and the gap-filling layer 126 by bonding the support substrate 142 to the integrated circuit dies 50B, the liner 128, and the gap-filling layer 126. For example, the support substrate 142 may be bonded to the bonding film 130 directly or through a bonding film 144. The bonding film 144 may be a film disposed on a surface of the support substrate 142 before being bonded to the bonding film 130. In some embodiments, the bonding film 144 may be a single layer or a composite layer including a plurality of sublayers. The single layer or the sublayers of the bonding film 144 may include an oxide such as silicon oxide, PSG, BSG, or BPSG; an oxynitride such as silicon oxynitride; an adhesive material such as die-attaching film (DAF) or thermal interface material (TIM); combinations thereof, or the like. The bonding film 144 and the bonding film 130 may have a similar material and be formed by a similar manner. In some embodiments, the bonding film 130 and the bonding film 144 may be bonded through dielectric-to-dielectric bonds, such as covalent bonds, or through the adhesive properties of the bonding film 130 and/or 144.

Next, in FIG. 10, a carrier substrate de-bonding is performed to detach (or “de-bond”) the carrier substrate 102 from the integrated circuit dies 50A. In an embodiment, the de-bonding includes projecting a light such as a laser light or a UV light on the release layer 104 so that the release layer 104 decomposes under the heat of the light, and therefore, the carrier substrate 102 can be removed. The structure is then flipped over and placed on a tape (not separately illustrated).

Next, conductive connectors 154, also referred to as external connectors of the IC package 100, are formed on the die connectors 74A. The conductive connectors 154 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 154 may include a conductive material such as solder, copper, aluminum, gold, nickel, silver, palladium, tin, the like, or a combination thereof. In the illustrated embodiment, the conductive connectors 154 include conductive bumps (e.g., copper pillars) with solder regions (labeled as 150) on the end surfaces of the conducive bumps. The conductive connectors 154 may be subsequently utilized to connect the integrated circuit package 100 to another component, such as an interposer, a packing substrate, or the like.

In some embodiments, the IC packages 100 are formed at a wafer level, and a singulation process may be performed to separate the IC packages 100 as individual packages. For example, a dicing process may be performed along dicing regions 146 to separate the IC packages 100 into individual packages. FIG. 11A illustrates an IC package 100 after the dicing process.

FIG. 11B illustrates a top view of the IC package 100 of FIG. 11A. For simplicity, not all elements of the IC package 100 are illustrated in FIG. 11B. In FIG. 11B, elements under the support substrate 142 are illustrated in phantom. FIG. 11A is the cross-section view along cross-section A-A′ of FIG. 11B.

As illustrated in FIG. 11B, the integrated circuit die 50B and the dummy die 82 are disposed within the boundary of the integrated circuit die 50A. FIG. 11B further illustrates another die (labeled as 50B/82), which may be another integrated circuit die 50B or another dummy die 82, attached to the integrated circuit die 50A. The die 50B/82 is not visible in the cross-section view of FIG. 11A. All the upper dies (e.g., 50B, 82, 50B/82) attached to the integrated circuit die 50A (also referred to as the lower die) are disposed within the boundary of the integrated circuit die 50A. FIG. 11B illustrates the closest distances (e.g., the closest lateral distances, or the smallest lateral offsets) between the sidewalls of each upper die and the sidewalls of the integrated circuit die 50A, which are labeled as D1, D2, and D3 in FIG. 11B. The closest distances D1, D2, and D3 are larger than 0 μm, such as between 0 μm and 80 μm, or are larger than one third of the thickness T of an upper die (e.g., integrated circuit die 50B), in some embodiments.

FIG. 11C shows the same top view as FIG. 11B, but with the dielectric liner 128 around the integrated circuit die 50B illustrated. As shown in FIG. 11C, the dielectric liner 128 (the portion shown) contacts and encircles the integrated circuit die 50B. In the top view, the exterior sidewalls of the dielectric liner 128 facing away from the integrated circuit dies 50B are disposed between sidewalls of the integrated circuit 50B and sidewalls of the integrated circuit die 50A. FIG. 11C further shows two other possible locations for the exterior sidewalls of the dielectric liner 128, labeled as 128′ and 128″, depending on the thickness of the dielectric liner 128 and the smallest lateral offset D1 (see FIG. 11B). One of the exterior sidewalls 128′ of the dielectric liner 128 is aligned with (e.g., overlaps) a closest sidewall of the integrated circuit die 50A along a same line. One of the exterior sidewalls 128″ of the dielectric liner 128 extends beyond the perimeter defined by the sidewalls of the integrated circuit die 50A.

FIG. 11D shows another example for the top view of the IC package 100 in FIG. 11A. FIG. 11D is similar to FIG. 11B, but without the die 50B/82. The number of upper dies attached to the integrated circuit die 50A shown in FIGS. 11B and 11D are merely non-limiting examples. The number of upper dies may be any suitable number, and the locations of the upper dies may be anywhere within the boundary defined by the sidewalls of the integrated circuit die 50A, as skilled artisans readily appreciate.

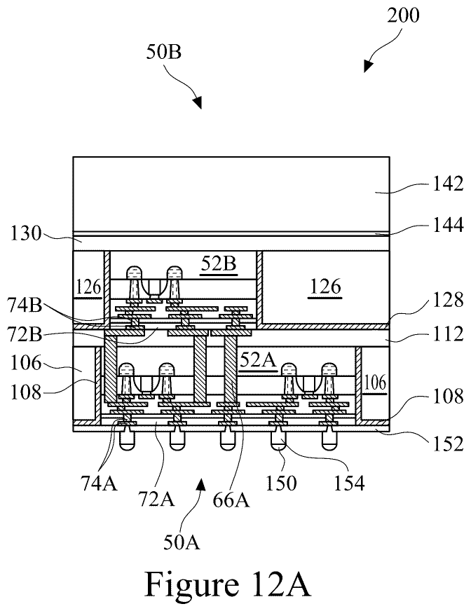

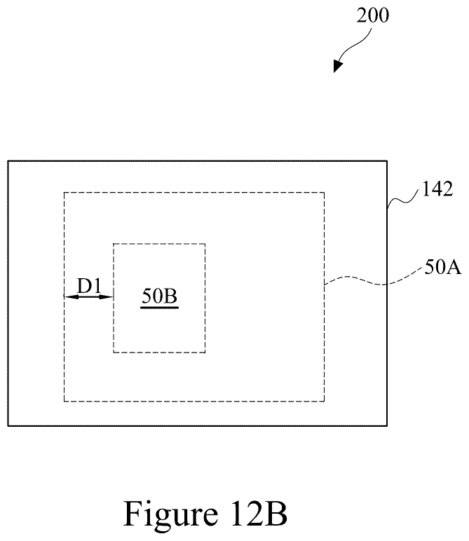

FIGS. 12A and 12B illustrate a cross-sectional view and a top view, respectively, of an integrated circuit package 200, in accordance with another embodiment. The IC package 200 is similar to the IC package 100, but with only one upper die 50B attached to the lower die 50A.

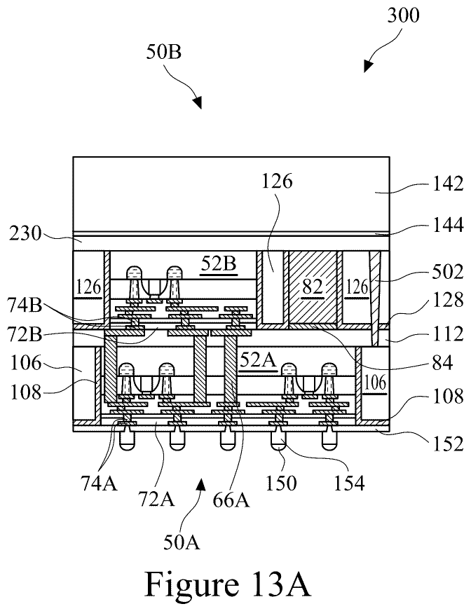

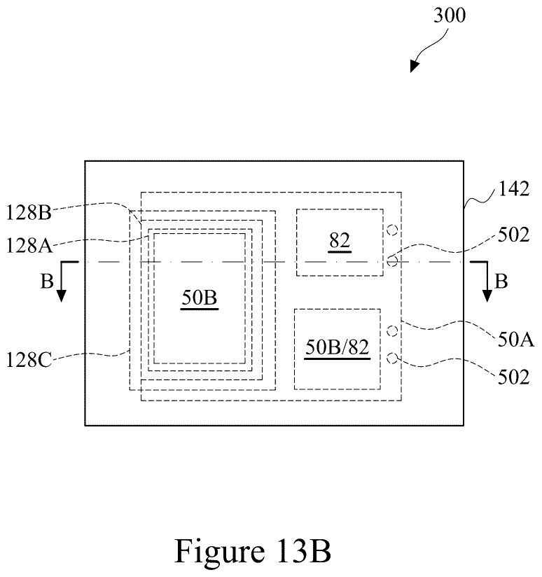

FIGS. 13A and 13B illustrate a cross-sectional view and a top view, respectively, of an integrated circuit package 300, in accordance with another embodiment. The IC package 300 is similar to the IC package 100, but with dummy vias 502 and with a metal film 230 replacing the bonding film 130 of FIG. 11A.

The IC package 300 may be formed by performing the processing steps in FIGS. 2-8A, then forming the dummy vias 502 in portions of the gap-filling material 126 overlying the gap-filling material 106. The dummy vias 502 may be formed by forming openings that extend through the gap-filling material 126, the dielectric liner 128, and the bonding film 112 to expose the underlying gap-filling material 106. The openings may also extend partially into the underlying gap-filling material 106. Next, a conductive material, such as copper, tungsten, or the like, may be formed in the openings. A planarization process, such as CMP, may be performed to remove excess portions of the conductive material that are disposed outside the openings. The remaining portions of the conductive material inside the openings form the dummy vias 502. Note the dummy vias 502 are electrically isolated, and are formed to improve heat dissipation of the device formed.

After the dummy vias 502 are formed, processing follows those of FIGS. 9 and 10. Note that the bonding film 130 in FIGS. 9 and 10 are replaced by a metal film 230 for improving the heat dissipation efficiency for the integrated circuit dies 50A and 50B. The metal film 230 may include copper, a copper alloy, silver, gold, tungsten, cobalt, aluminum, nickel, iron, an alloy thereof, a combination thereof, or the like, and may be formed by electroplating, electroless plating, CVD, PVD, or other suitable methods. In this embodiment, the bonding film 144 may use an adhesive material such as thermal interface material (TIM) or a die-attaching film (DAF) for attaching the support substrate 142 to the metal film 230.

FIGS. 14A and 14B illustrate a cross-sectional view and a top view, respectively, of an integrated circuit package 400, in accordance with another embodiment. The IC package 400 is similar to the IC package 100, but with the integrated circuit dies 50B attached to the bonding film 112 in a back-to-face manner, such that the back-side of the integrated circuit die 50B is attached to the front-sides of the integrated circuit dies 50A. In addition, conductive vias 66B are formed to extend through the substrate 52B of the integrated circuit die 50B, and to be electrically coupled to the integrated circuit die 50A.

The IC package 400 may be formed by: following the similar processing steps similar to those of FIGS. 2-4 to form the lower structures of the IC package 400 comprising the integrated circuit dies 50A, but with the back-sides of the integrated circuit dies 50A attached to the carrier 102, and no conductive vias 66A are formed in the integrated circuit dies 50A; following similar processing steps of FIGS. 2-6 to form the upper structures of the IC package 400 comprising the integrated circuit dies 50B on a second carrier, with conductive vias 66B formed in the integrated circuit dies 50B and with dummy die 82 attached to the second carrier; flipping the second carrier with the upper structures up-side-down, and bonding the upper structures with the corresponding lower structures; after the bonding, removing the second carrier attached to the upper structure and forming conductive connectors 154 on the die connectors 74B of the integrated circuit dies 50B; and performing dicing to form individual IC packages 400. Note that in IC package 400, the conductive connectors 154 are formed on the integrated circuit dies 50B, and the carrier 102 remains in the final IC package 400.

FIG. 15 illustrate a cross-sectional view of an integrated circuit package 500, in accordance with another embodiment. The IC package 500 is similar to the IC package 400, but with the integrated circuit dies 50B attached to the integrated circuit die 50A in a face-to-face manner, such that the front-side of the integrated circuit die 50B is attached to the front-side of the integrated circuit die 50A. In addition, conductive vias 66B are formed to extend through the substrate 52B of the integrated circuit die 50B, and to be electrically coupled to the integrated circuit die 50A.

Skilled artisans, upon reading the disclosure herein, would be able to readily adapt the processing steps disclosed herein to form the IC package 500, thus details are not discussed here. The top view of the IC package 500 may be same as or similar to that of FIG. 14B, thus not repeated.

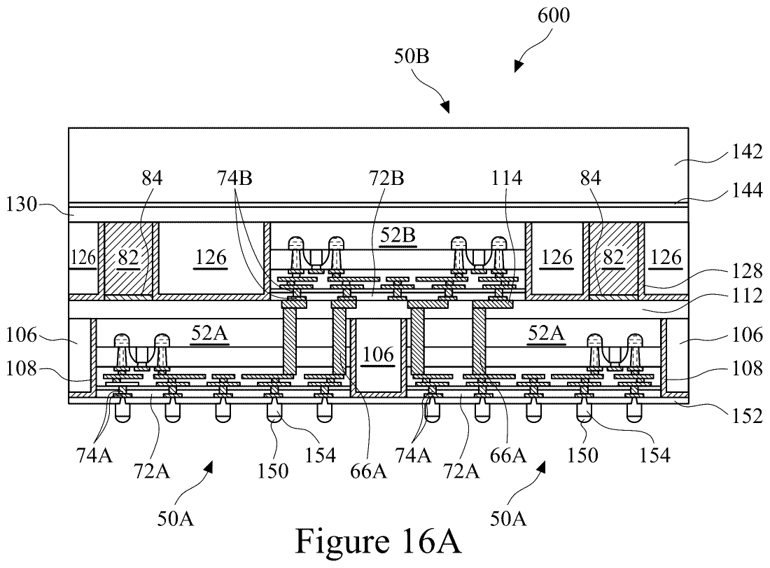

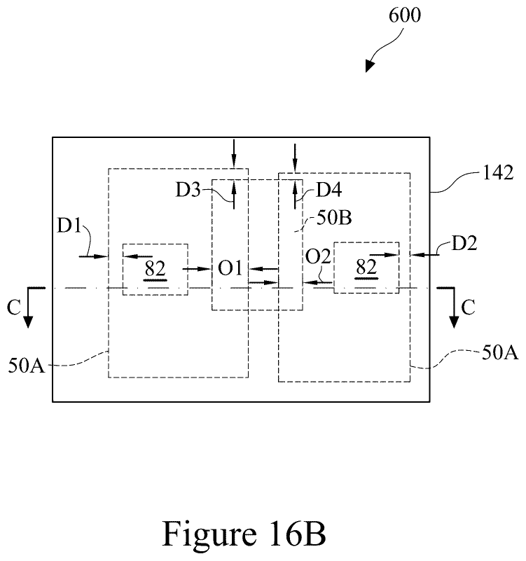

FIGS. 16A and 16B illustrate a cross-sectional view and a top view, respectively, of an integrated circuit package 600, in accordance with yet another embodiment. The IC package 600 is similar to the IC package 100, but with two integrated circuit dies 50A in the lower structure, and with the integrated circuit dies 50B in the upper structure overlapping with both integrated circuit dies 50A. Skilled artisans, upon reading the disclosed herein, would be able to readily adapt the processing steps for IC package 100 to form the IC package 600, thus details are not discussed here.

FIG. 16B illustrates the top view of the IC package 600. In FIG. 16B, the distance D1, D2, D3, and D4 shows the closest lateral distances between sidewalls of the different dies (e.g., 50A, 50B, 82). In addition, FIG. 16B shows offsets O1 and O2, which are the overlapping distances between the integrated circuit die 50B and the integrated circuit dies 50A. In some embodiments, the closest lateral distances D1, D2, D3, and D4, and the overlapping distances O1 and O2 are larger than zero (e.g., between 0 μm and about 80 μm), and may be larger than one third of the thickness T of the integrated circuit die 50B.

Variations to the disclosed embodiments are possible and are fully intended to be included within the scope of the present disclosure. For example, the various disclosed IC packages have a two-storied structure, e.g., a lower structure and an upper structure over the lower structure. The IC packages may have more than two stories of structures, with each story of structure labeled as story 1, 2, 3, . . . , and so on. In a top view, the sidewalls of integrated circuit dies in story N+1 are disposed within, and are spaced apart from, sidewalls of the underlying integrated circuit die in story N. As another example, features in different embodiments may be combined in different ways to form new embodiments.

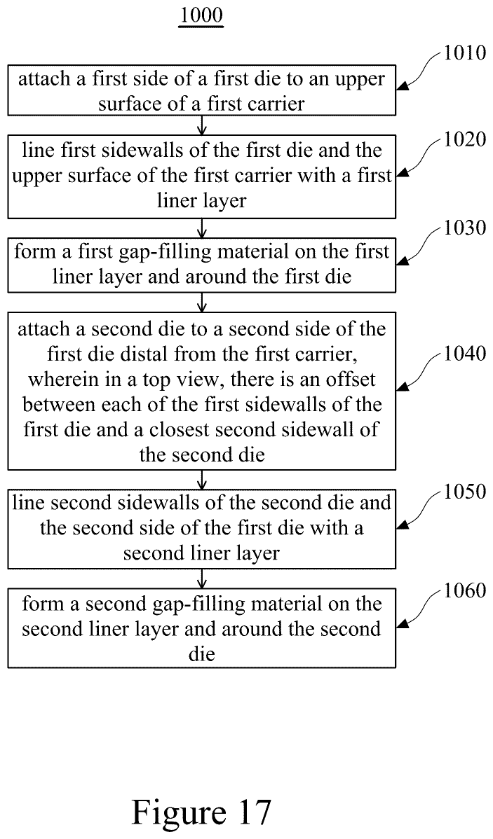

FIG. 17 is a flow chart of a method 1000 of forming a semiconductor device, in some embodiments. It should be understood that the embodiment method shown in FIG. 17 is merely an example of many possible embodiment methods. One of ordinary skill in the art would recognize many variations, alternatives, and modifications. For example, various steps as illustrated in FIG. 17 may be added, removed, replaced, rearranged, or repeated.

Referring to FIG. 17, at block 1010, a first side of a first die is attached to an upper surface of a first carrier. At block 1020, first sidewalls of the first die and the upper surface of the first carrier are lined with a first liner layer. At block 1030, a first gap-filling material is formed on the first liner layer and around the first die. At block 1040, a second die is attached to a second side of the first die distal from the first carrier, wherein in a top view, there is an offset between each of the first sidewalls of the first die and a closest second sidewall of the second die. At block 1050, second sidewalls of the second die and the second side of the first die are lined with a second liner layer. At block 1060, a second gap-filling material is formed on the second liner layer and around the second die.

Disclosed embodiments may achieve advantages. For example, by placing the upper dies (e.g., 50B, 82) within the boundary of the lower die (e.g., 50A), issues such as delamination of bonding film, peeling off of the upper dies, and warpage of the IC package can be avoided or alleviated. Additional features, such as the dummy conductive vias and the metal film, help to improve efficiency of heat dissipation, thereby improving the performance of the device formed.

In an embodiment, a device includes: a first integrated circuit (IC) die; a first dielectric material around first sidewalls of the first IC die; a second IC die over and electrically coupled to the first IC die; and a second dielectric material over the first dielectric material and around second sidewalls of the second IC die, wherein in a top view, the second sidewalls of the second IC die are disposed within, and are spaced apart from, the first sidewalls of the first IC die. In an embodiment, a closest lateral distance between the first sidewalls of the first IC die and the second sidewalls of the second IC die is larger than one third of a thickness of the second IC die. In an embodiment, a closest lateral distance between the first sidewalls of the first IC die and the second sidewalls of the second IC die is larger than 0 μm and smaller than about 80 μm. In an embodiment, the device further comprises: external connectors at a front-side of the first IC die distal from the second IC die; and through-substrate vias (TSVs) extending through a first substrate of the first IC die, wherein the TSVs protrudes above a back-side of the first substrate distal from the external connectors, wherein the second IC die is electrically coupled to the TSVs. In an embodiment, the device further comprises: a bonding film between the first IC die and the second IC die; and conductive pads in the bonding film, wherein the TSVs extends into the bonding film and are coupled to respective ones of the conductive pads, wherein the second IC die is bonded to the conductive pads. In an embodiment, die connectors of the second IC die are bonded to the conductive pads through metal-to-metal bonding, wherein an exterior dielectric layer of the second IC die is bonded to the bonding film through dielectric-to-dielectric bonding. In an embodiment, the device further includes a dummy die laterally adjacent to the second IC die, wherein the dummy die is over and attached to the bonding film, wherein in the top view, third sidewalls of the dummy die are disposed within, and are spaced apart from, the first sidewalls of the first IC die. In an embodiment, the device further includes a dummy via that extends through the second dielectric material, through the bonding film, and contacts the first dielectric material. In an embodiment, the device further includes: a first liner layer between the first IC die and the first dielectric material, wherein the first liner layer contacts and extends along the first sidewalls of the first IC die; and a second liner layer between the second IC die and the second dielectric material, wherein the second liner layer contacts and extends along the second sidewalls of the second IC die. In an embodiment, the second liner layer has a different composition than the first liner layer. In an embodiment, a second Young's modulus of the second liner layer is smaller than a first Young's modulus of the first liner layer. In an embodiment, the first liner layer is a single-layer dielectric material, and the second liner layer has a multi-layered structure and comprises a plurality of sublayers, wherein each of the sublayers is a different dielectric material.

In an embodiment, a device includes: a first die; a first liner layer extending along first sidewalls of the first die; a first dielectric material on the first liner layer and around the first die; a second die over and electrically coupled to the first die; a second liner layer extending along second sidewalls of the second die and along a first surface of the first dielectric material facing the second die; and a second dielectric material on the second liner layer and around the second die, wherein there is lateral offset between each of the first sidewalls of the first die and a closest second sidewall of the second die. In an embodiment, in a top view, the second die is disposed within a perimeter defined by the first sidewalls of the first die, and a closest distance between the first sidewalls and the second sidewalls is larger than one third of a thickness of the second die. In an embodiment, the device further includes: a dielectric film between, and contacting, the first die and the second die; through-substrate-vias (TSVs) coupled between a first interconnect structure of the first die and a second interconnect structure of the second die, wherein the TSVs extend through a first substrate of the first die, or through a second substrate of the second die; and conductive pads in the dielectric film, wherein the TSVs extend into the dielectric film, and are coupled to the conductive pads. In an embodiment, the second liner layer is softer than the first liner layer. In an embodiment, the first liner layer has a homogeneous composition, wherein the second liner layer has a plurality of sublayers, and each of the sublayers is a different dielectric material.

In an embodiment, a method of forming a device includes: attaching a first side of a first die to an upper surface of a first carrier; lining first sidewalls of the first die and the upper surface of the first carrier with a first liner layer; forming a first dielectric material on the first liner layer and around the first die; attaching a second die to a second side of the first die distal from the first carrier, wherein in a top view, there is an offset between each of the first sidewalls of the first die and a closest second sidewall of the second die; lining second sidewalls of the second die and the second side of the first die with a second liner layer; and forming a second dielectric material on the second liner layer and around the second die. In an embodiment, a closest lateral distance between the first sidewalls of the first die and the second sidewalls of the second die is larger than one third of a thickness of the second die. In an embodiment, the method further includes: forming through-substrate-vias (TSVs) that extend through a first substrate of the first die, or through a second substrate of the second die, wherein the TSVs are electrically coupled to the first die and the second die; and forming a bonding film between the first die and the second die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) package comprising:
a first dielectric material;
a first die embedded in the first dielectric material;
a first liner layer between the first dielectric material and the first die, wherein the first liner layer extends along first sidewalls of the first die;
a second dielectric material over the first dielectric material and the first die;
a second die embedded in the second dielectric material; and
a second liner layer between the second dielectric material and the second die, wherein the second liner layer extends along second sidewalls of the second die, wherein in a top view, the second sidewalls of the second die are disposed within the first sidewalls of the first die, and a smallest distance between the second sidewalls of the second die and the first sidewalls of the first die is larger than one third of a thickness of the second die.

2. The IC package of claim 1, wherein the smallest distance is larger than 0 μm and smaller than about 80 μm.

3. The IC package of claim 1, wherein a second Young's modulus of the second liner layer is smaller than a first Young's modulus of the first liner layer.

4. The IC package of claim 3, wherein a second thickness of the second liner layer is larger than a first thickness of the first liner layer.

5. The IC package of claim 1, wherein the first liner layer is a single-layer dielectric material, and the second liner layer is a multi-layered dielectric structure that comprises a plurality of sublayers.

6. The IC package of claim 5, wherein each of the plurality of sublayers has a different material composition.

7. The IC package of claim 5, wherein the second liner layer comprises a first sublayer contacting the second die, and comprises a second sublayer contacting the second dielectric material, wherein a Young's modulus of the first sublayer is smaller than that of the second sublayer.

8. The IC package of claim 7, wherein the second liner layer further comprises a third sublayer between the first sublayer and the second sublayer, wherein a Young's modulus of the third sublayer is between that of the first sublayer and that of the second sublayer.

9. A method of forming an integrated circuit package, the method comprising:
attaching a first side of a first die to a first surface of a carrier;
forming a first liner layer along first sidewalls of the first die and along the first surface of the carrier;
depositing a first encapsulant material over the first surface of the carrier and around the first liner layer and the first die;
after depositing the first encapsulant material, attaching a second die to a second side of the first die distal from the carrier, wherein in a top view, the second die is disposed within a boundary defined by the first sidewalls of the first die;
forming a second liner layer along second sidewalls of the second die and along an upper surface of the first encapsulant material distal from the carrier; and
forming a second encapsulant material over the first encapsulant material and around the second liner layer and the second die.

10. The method of claim 9, wherein in the top view, a minimum distance between the second sidewalls of the second die and the first sidewalls of the first die is larger than one third of a thickness of the second die.

11. The method of claim 9, wherein the first liner layer is formed to be a single-layer dielectric material, and the second liner layer is formed to be a multi-layered dielectric structure that includes a plurality of sublayers, wherein each of the plurality of sublayers has a different material composition.

12. The method of claim 11, wherein the multi-layered dielectric structure comprises a first sublayer contacting the second die, and comprises a second sublayer contacting the second encapsulant material, wherein a Young's modulus of the first sublayer is smaller than that of the second sublayer.

13. The method of claim 12, wherein the multi-layered dielectric structure further comprises a third sublayer interposed between the first sublayer and the second sublayer, wherein a Young's modulus of the third sublayer is between that of the first sublayer and that of the second sublayer.

14. The method of claim 9, wherein the first liner layer is formed to have a first thickness, wherein the second liner layer is formed to have a second thickness larger than the first thickness.

15. The method of claim 14, wherein the first liner layer is formed of a first dielectric material having a first Young's modulus, wherein the second liner layer is formed of a second dielectric material having a second Young's modulus smaller than the first Young's modulus.

16. The method of claim 9, further comprising, before forming the second liner layer, attaching a dummy die to the upper surface of the first encapsulant material, wherein the dummy die is laterally adjacent to the second die, wherein the second liner layer is formed to extend along sidewalls of the dummy die.

17. The method of claim 16, further comprising, after forming the second encapsulant material, forming a dummy via using a metal material, wherein the dummy via is formed laterally adjacent to the dummy die, and is formed to extend through the second encapsulant material and into the first encapsulant material.

18. A method of forming an integrated circuit package, the method comprising:
forming a first liner layer along first sidewalls of a first die, wherein the first liner layer is a single-layer dielectric material;
encapsulating the first die and the first liner layer with a first dielectric material;
positioning a second die over the first die and the first dielectric material, wherein in a top view, the second die is disposed within a perimeter defined by the first sidewalls of the first die;
forming a second liner layer along second sidewalls of the second die, wherein the second liner layer is a multi-layered dielectric structure that comprises a plurality of sublayers, wherein each sublayer of the plurality of sublayers comprises a different dielectric material; and
encapsulating the second die and the second liner layer with a second dielectric material.

19. The method of claim 18, wherein in the top view, a minimum distance between the second sidewalls of the second die and the first sidewalls of the first die is larger than one third of a thickness of the second die.

20. The method of claim 19, wherein the multi-layered dielectric structure is formed to have a gradient in a hardness of the plurality of sublayers, wherein the hardness of the plurality of sublayers increases along a direction from the second die toward the second dielectric material.
